(19) United States
(12) Patent Application Publication
(10) Pub. No.: US 2008/0081398 A1
(43) Pub. Date: Apr. 3, 2008

(54) Cap Wafer for Wafer Bonded Packaging and Method for Manufacturing the Same

(75) Inventors: Sang-Hwan Lee, Daejeon (KR); Yeon-Duck Ryu, Daejeon (KR); Jae-Yong An, Daejeon (KR); Hyun-Jin Choi, Daejeon (KR); Myoung-Seon Shin, Daejeon (KR)

Correspondence Address: THE WEBB LAW FIRM, P.C., 700 KOPPERS BUILDING, 436 SEVENTH AVENUE, PITTSBURGH, PA, 15219, US

(73) Assignee: FIONIX INC., Daejeon (KR)

(21) Appl. No.: 11/866,277

(22) Filed: Oct. 2, 2007

(30) Foreign Application Priority Data
Oct. 2, 2006 (KR) 10-2006-0097218

(51) Int. Cl. H01L 21/00

(52) U.S. Cl. 438/109; 257/E21.001

(57) ABSTRACT

The present invention relates to semiconductor device manufacturing techniques, and specifically to a field of device packaging techniques at wafer level. More specifically, it relates to a cap wafer for wafer bonding application that is bonded to top part of a device wafer. The method of the present invention excludes the use of deep reactive ion etching of silicon to form a through silicon via. The present invention provides a method for the preparation of cap wafer for wafer bonding application with a simple process of through silicon via interconnection and a wafer level packaging method using the same.

### TECHNICAL FIELD

The present invention relates to semiconductor device manufacturing techniques, and specifically to a field of wafer level packaging techniques. More specifically, it relates to a cap wafer for wafer bonded hermetic packaging that is bonded to top of device wafer.

### BACKGROUND ART

Wafer level Packaging of semiconductor device by wafer bonding is a batch, mass-production method which from hundreds to thousands of devices are packaged simultaneously. Therefore, it is advantageous in that packaging cost can be reduced. Wafer level packaging using wafer bonding can be categorized into the one for general integrated circuit devices such as memory devices, etc. and the other for sensor/MEMS (Microelectromechanical Systems) having sensing element or mechanically moving structure on the surface of device.

For general IC field, the major object of wafer bonding technique is to stack chips three-dimensionally, thus it is mainly used for increasing the integration density or for preparing a complex chip wherein heterogeneous ICs are integrated. On the other hand, for sensor/MEMS field, wafer bonding techniques are used to protect devices such as sensor, etc. that are sensitive to contamination from outside environments and structural bodies such as diaphragm that are mechanically fragile. Therefore, a means to provide a hermetic sealing of devices are required in many cases.

For wafer level packaging by using wafer bonding technique, a means of through wafer via interconnection connecting the electrodes which drive device and extract their response from the bonding surface to the outside of the bonded wafer is commonly required for both of general IC and sensor/MEMS. Number of via is quite high for general IC, while it is often low for sensor/MEMS.

The most widely used method of via interconnection in wafer level packaging is forming through silicon via by deep reactive ion etching and filling it with conductive metals such as copper (Cu) by electroplating to achieve an electrical connection. Such method is advantageous in that, the area of contact pads occupied by via is small and the thickness of packaged wafer can be reduced by thinning the backside of bonded cap wafer after wafer bonding. However, deep reactive ion etching and copper-filling processes are known as most costly among the semiconductor fabrication processes, and moreover copper-filling that is typically performed by plating technique requires very long process time. Therefore for the wafer level packaging of sensor/MEMS devices, in which the number of via is limited, more simple and economic method of through silicon via formation is required.

FIG. 1 shows a cross-section of a cap wafer for wafer level packaging application in which through silicon via was formed by anisotropic silicon wet etching (see, U.S. Pat. No. 6,429,511).

According to said through-hole interconnection process, feed-through metal layer and hermetic sealing are provided simultaneously without using deep reactive ion etching or copper filling method. Specifically, FIG. 1 represents a semiconductor cap wafer which is used as a cap for subassembly of optoelectronic integrated circuit, a structure suitable for a wafer-level packaging equipment for optical device comprising feed-through metal layer (7), wire bonding pad (4) and a soldering material (8) for bonding to a device wafer (not shown).

By using SOI (Silicon On Insulator) wafer having silicon oxide layer (2) buried in the middle of silicon wafer (1), one or more of top side through-holes (6) and bottom side through-holes (5), that are matching to each other regardless of the order of the top and bottom sides of the wafer, are formed by anisotropic wet etching of silicon. The buried silicon oxide layer (2) of SOI wafer serves as an etch stop layer when bottom side through-holes (5) and top side through-holes (6) are being etched. After bottom side through-holes (5) and top side through-holes (6) are formed on the top and bottom sides of the wafer, respectively, the buried silicon oxide layer (2) in the region of top side through-holes (6) is removed while the top and bottom sides of the wafer are allowed to communicate with each other via bottom side through-holes (5) and top side through-holes (6).

Then, over the entire surface region of the wafer comprising bottom side through-holes (5) and top side through-holes (6), photoresist coating is carried out. By patterning said coating using a photolithography technique, a region in which feed-through metal layer (7) is to be formed is defined, and feed-through metal layer (7) is formed therein by electroplating. Feed-through metal layer (7) is set thick enough to fill completely the through-holes connecting the top and bottom sides of the wafer. In FIG. 1, unspecified number ‘3’ indicates silicon nitride layer which is used to selectively expose a certain region of feed-through metal layer (7).

The above-described conventional through-hole interconnection method is advantageous in that it uses anisotropic wet etching of silicon on behalf of costly deep reactive ion etching. However, such conventional through-hole interconnection method is problematic in that SOI wafer, which is more expensive than general silicon wafer, is required and due to the complexity for forming interconnection in the presence of already formed through-holes which penetrate the top and bottom sides of the wafer, it accompanies a disadvantage that production cost is high to exceed the savings expected from replacing deep reactive ion etching.

[Technical Subject]

The present invention is to solve the above-described problems of prior art. The object of the present invention is to provide a method for manufacturing a cap wafer for wafer level packaging by wafer bonding with a simple through silicon via interconnection methods wherein the use of deep reactive ion etching of silicon is excluded.

Further, another object of the present invention is to provide a wafer level packaging method which can be used for hermetic sealing of devices by utilizing the through silicon via interconnection between the above-described cap wafer and a device wafer.

### DISCLOSURE OF INVENTION

In order to achieve the object of the invention described above, the present invention provides a method for preparing a silicon cap wafer and a wafer level hermetic packaging method using the same. The method for preparing a cap wafer according to the present invention comprises the following steps of: i) forming an etch mask layer on the top and back side of a silicon wafer; ii) patterning said etch mask layer to form a cavity etch window on the back side of said silicon wafer, and then forming a via etch window on the top side of said silicon wafer to overlap with said cavity etch window; iii) forming cavities and vias by wet etching of said silicon wafer that has been exposed by said cavity etch window and said via etch window, provided that a silicon substrate with certain thickness is maintained between said cavity and said via; iv) forming cavity interconnection and a wafer bonding pad on the back side of said silicon wafer to which said cavity has been formed; v) etching additionally said vias to expose said cavity interconnection; vi) forming through silicon via interconnection which contacts said cavity interconnection on the top side of said silicon wafer with said through silicon via are formed thereon; and vii) with a metallic bonding material, forming a device contact pad on said cavity interconnection which is present on the peripheral of said cavity and a hermetic seal ring on top of said wafer bonding pad.

One aspect of the silicon cap wafer manufacturing and wafer bonding method according to the present invention comprises the following steps of: i) forming an etch mask layer on the top and back side of a silicon wafer; ii) patterning said etch mask layer to form a cavity etch window on the back side of silicon wafer, and then forming a via etch window on the top side of said silicon wafer to overlap with said cavity etch window; iii) forming cavities and vias by wet etching of said silicon wafer that has been exposed by said cavity etch window and said via etch window, provided that a silicon substrate with certain thickness is maintained between said cavity and said via; iv) forming cavity interconnection and a wafer bonding pad on the back side of said silicon wafer to which said cavity has been formed; v) etching additionally said vias to expose said cavity interconnection; vi) forming via interconnection which contacts said cavity interconnection on the top side of said silicon wafer with said through silicon via formed thereon; vii) with a metallic bonding material, forming a device contact pad on said cavity interconnection which is present on the peripheral of said cavity and a hermetic seal ring on top of said wafer bonding pad; and viii) bonding the cap silicon wafer wherein said device contact pad and said hermetic seal ring have been formed to the device wafer wherein the bonding pads which are one to one matched to cap wafer has been formed.

Another aspect of the silicon cap wafer fabrication according to the present invention comprises the following steps of: i) forming an etch mask layer on the top and back sides of a silicon wafer; ii) patterning said etch mask layer to form a cavity etch window on the back side of said silicon wafer, and then forming a via etch window on the top side of said silicon wafer to overlap with said cavity etch window; iii) forming cavities and vias by wet etching of said silicon wafer that has been exposed by said cavity etch window and said via etch window, provided that a silicon substrate with certain thickness is maintained between said cavity and said via; iv) forming cavity interconnection and a wafer bonding pad on the back side of said silicon wafer to which said cavity has been formed; v) with a metallic bonding material, forming a device contact pad on said cavity interconnection which is present on the peripheral of said cavity, and then forming a hermetic seal ring on top of said wafer bonding pad; vi) bonding the cap wafer wherein said device contact pad and said hermetic seal ring have been formed to the device wafer wherein the bonding pads which are one to one matched to cap wafer has been formed; vii) etching additionally said vias to expose said cavity interconnection; and viii) forming via interconnection which electrically connects said cavity interconnection on the top side of said silicon wafer to the top surface of said silicon wafer through the exposed cavity interconnection.

### BRIEF DESCRIPTION OF DRAWINGS

FIG. 1 shows a cross-section of a cap wafer fabricated by conventional through-hole interconnection process.

FIGS. 2a to 2k are flow charts showing steps of a method for fabricating silicon cap wafers according to one example of the present invention.

FIG. 3 shows a layout of a cavity, cavity interconnections and wafer bonding pads which corresponds to FIG. 2g mentioned above.

FIG. 4 shows a layout of via and via interconnection which corresponds to FIG. 2j mentioned above.

FIG. 5 shows a layout of wafer bonding pads and wafer seal ring which corresponds to FIG. 2k mentioned above.

FIG. 6 illustrates a cross-section of a wafer level package according to the first embodiment of the present invention.

FIGS. 7a to 7c show steps of a method to open via contact according to another example of the present invention.

FIGS. 8a to 8e are flow charts showing steps of a method for fabricating silicon cap wafer and wafer level package according to another example of the present invention.

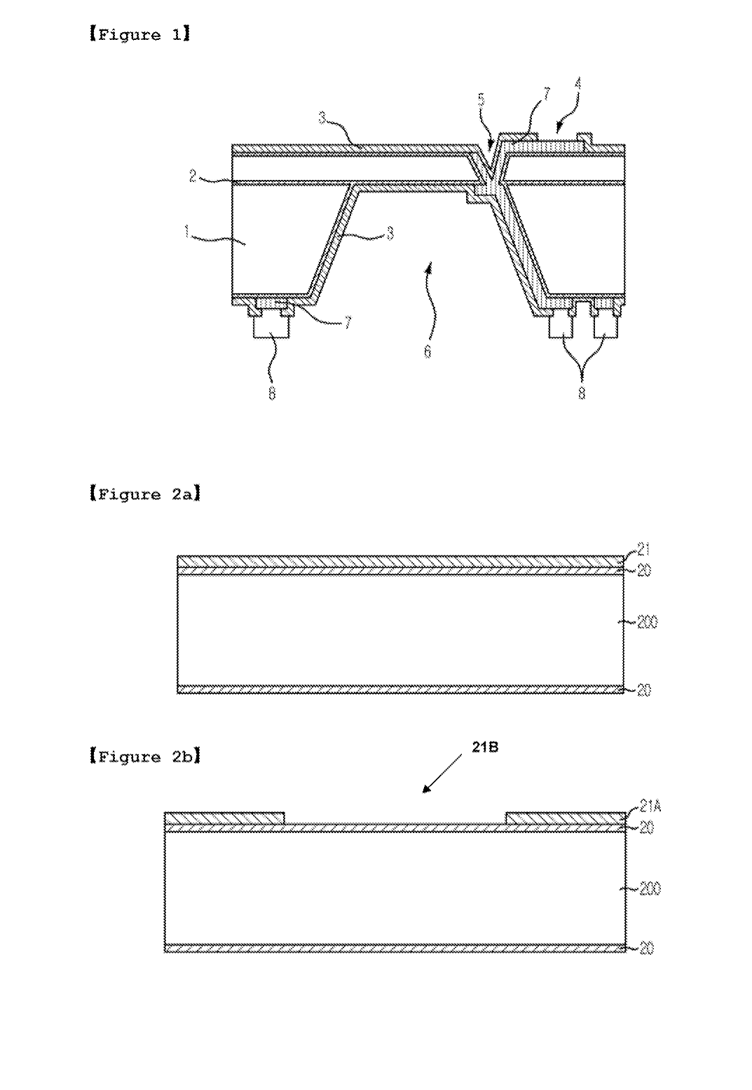

### EXPLANATION OF SYMBOLS FOR MAIN PART OF THE FIGURES

200: silicon cap wafer
300: device wafer

### BEST MODE FOR CARRYING OUT THE INVENTION

Hereinafter, preferred examples of the present invention will be provided so that those skilled in the art can easily carry out the present invention.

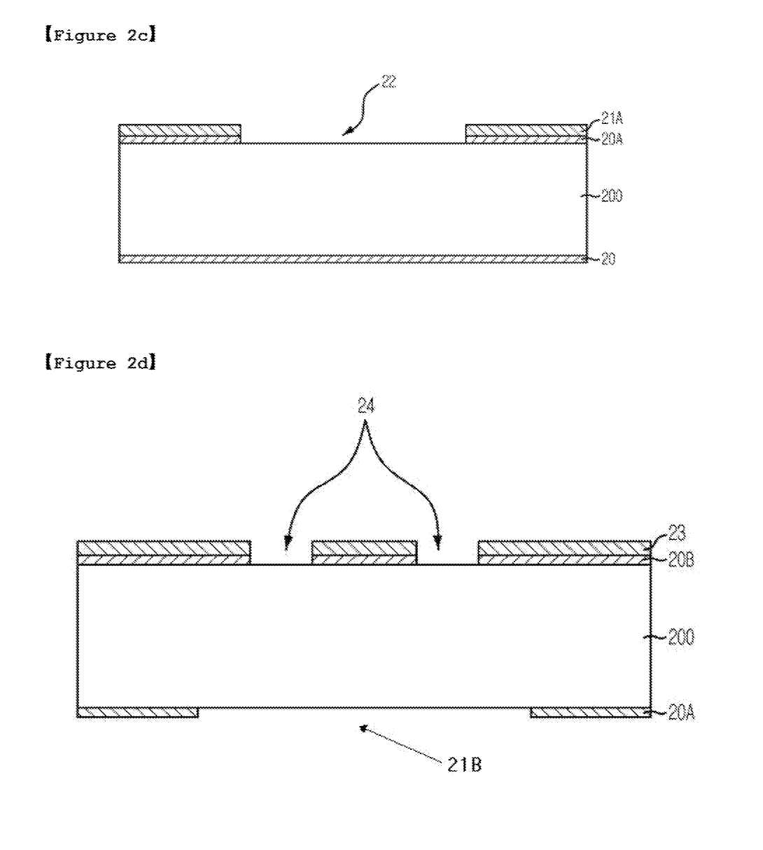

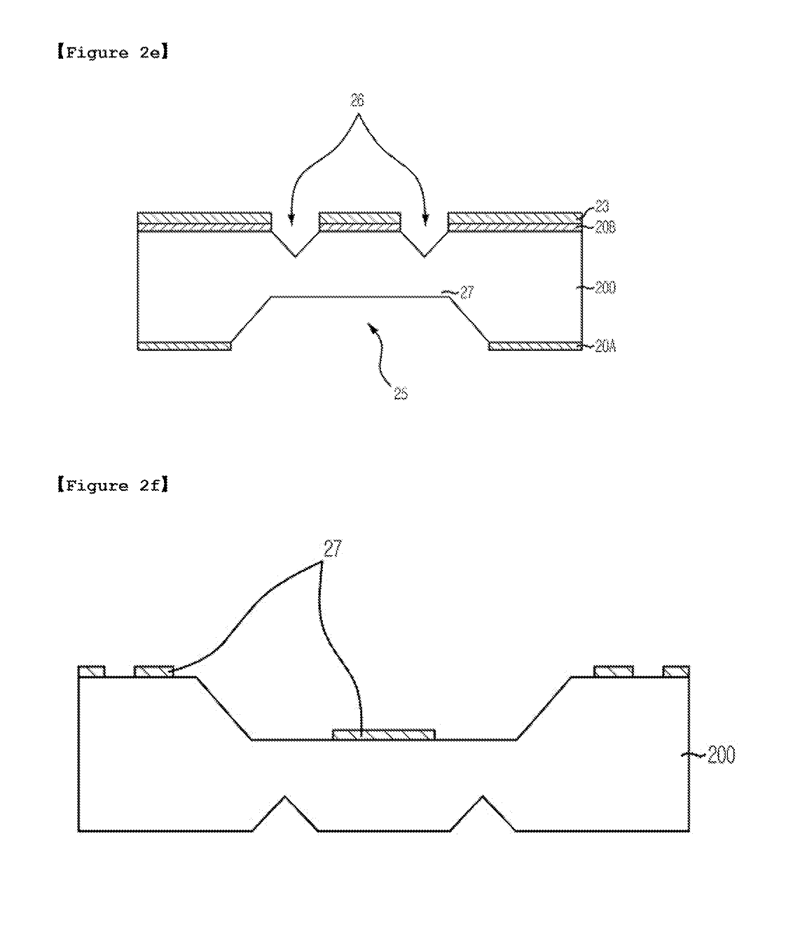

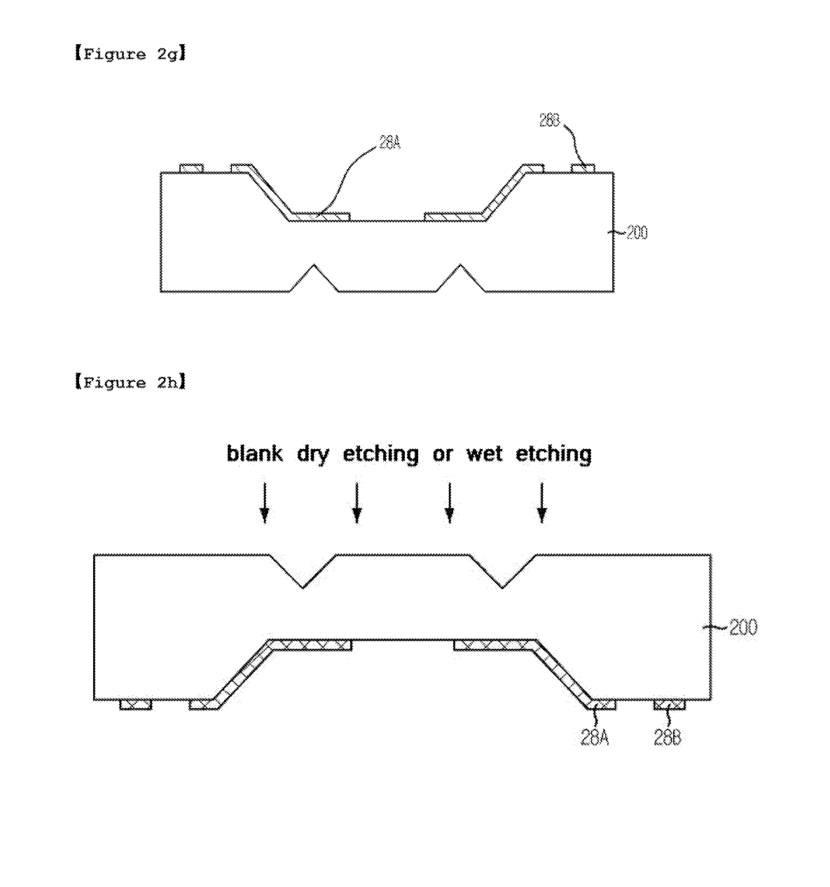

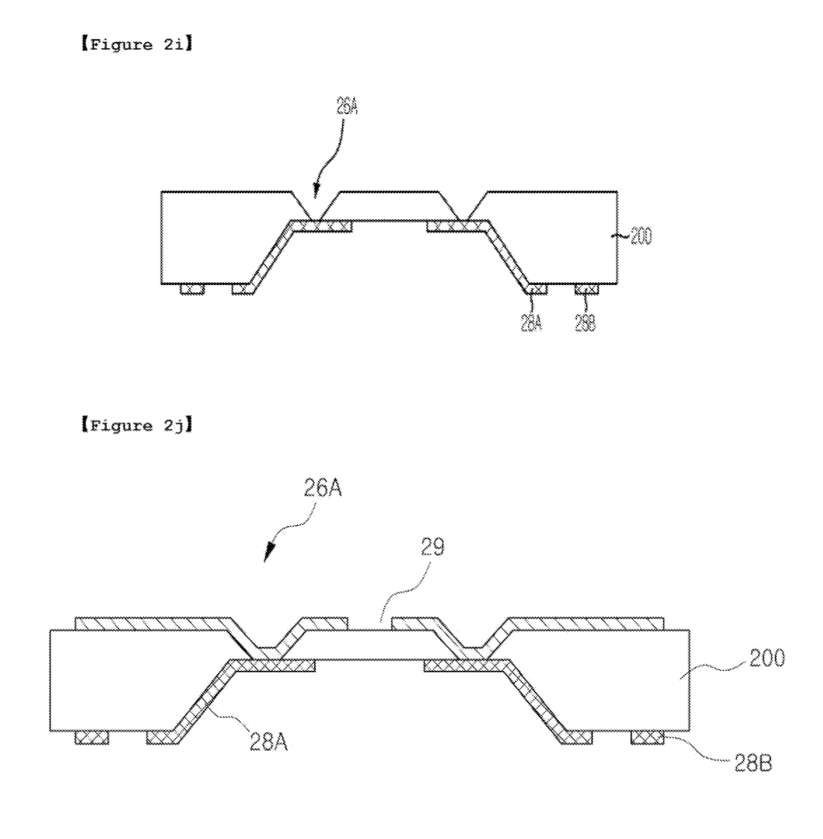

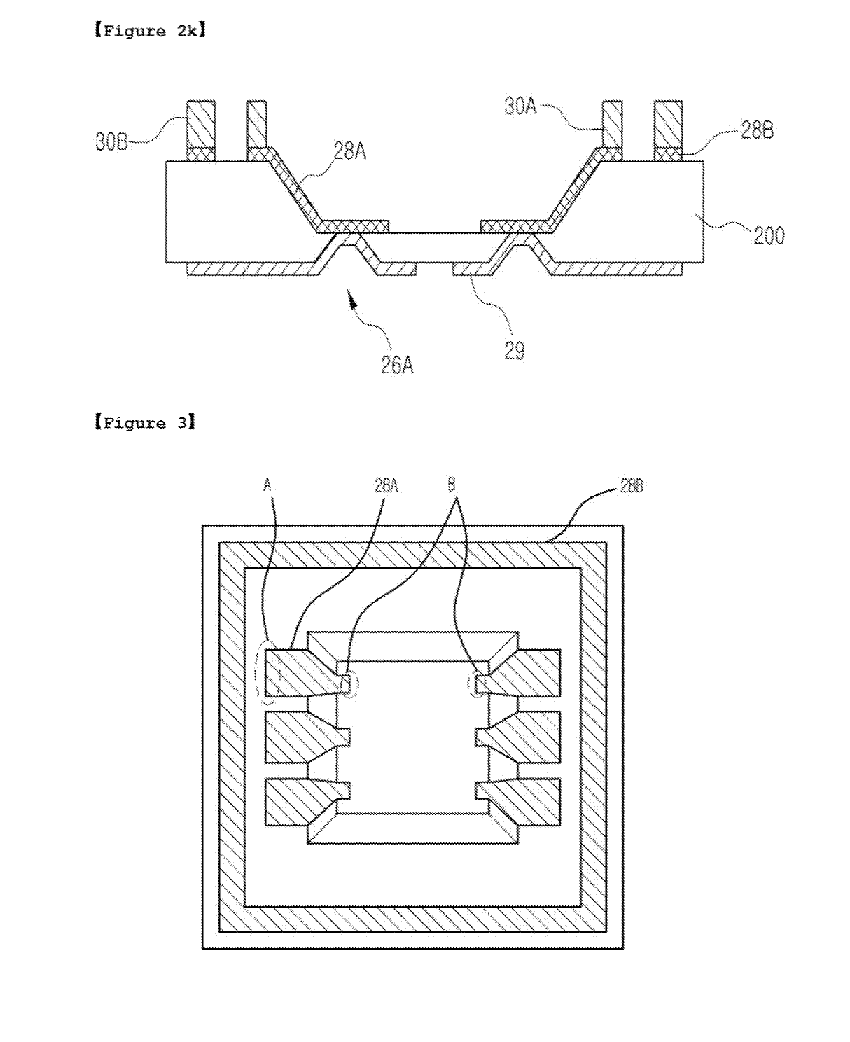

FIGS. 2a to 2k are flowcharts showing steps of a method for fabricating silicon cap wafers according to one example of the present invention.

The wafer level packaging process according to one example of the present invention comprises steps of depositing an etch mask layer (20) on the top and bottom sides of a silicon wafer (200) having (100) crystal plane and coating photoresist (21) on the top side of the silicon wafer (200), as shown in FIG. 2a. For the etch mask layer (20), it is preferred to use silicon oxide layer, silicon nitride layer or stacked layer of silicon oxide layer and silicon nitride layer.

Subsequently, as shown in FIG. 2b, cavity etch window (21B) is defined by selectively removing the photoresist (21A) on the cavity etch window by using photolithography techniques.

Next, as shown in FIG. 2c, the etch mask layer (20) in the cavity etch window (21B) is removed to expose silicon substrate (22) on the cavity etch window by dry or wet etching by using the photoresist pattern (21A) as an etch mask.

As a next step, as shown in FIG. 2d, the photoresist (23) on the back side of the silicon wafer (200) is patterned by photolithography process to define via etch window and followed by etch mask etching process with the same procedure described for the formation of the cavity etch window (22). In FIG. 2d, ‘21B’ and 24B indicate cavity etch window and via etch window, respectively. It is preferred that the cavity etch window (21B) and via etch window (24) are formed in a rectangular shape, respectively, and their four sides are aligned to be parallel with [110] crystalline orientation of (100) silicon wafer (200).

Next, Referring to FIG. 2e, the silicon wafer (200) is dipped into an anisotropic silicon etching solution such as KOH (potassium hydroxide) and TMAH (tetramethyl ammonium hydroxide) to etch the exposed silicon substrate to predetermined depth. In doing so, silicon diaphragm having certain thickness is temporarily to be remained so that cavity (25) and via (26) are not getting through to each other. When the diaphragm thickness is in the range of 10˜20 μm its removal at later step can be easier. Depth of cavity (25) and via (26) can be the same. However, it is also acceptable to have their depth set differently to each other. For the etch pattern aligned to be parallel with [110] crystalline orientation of the silicon substrate having (100) crystal plane, the maximum etch depth is automatically determined by the broader width of the etch window, in accordance with an intrinsic characteristic of anisotropic wet etching. Therefore, even when cavity (25) and via (26) are etched simultaneously, via (26) having shallower etch depth than that of cavity (25) can be formed by suitably designing the width of via etch window (24). Meanwhile, in order to form via (26) having deeper depth compared to the etch depth of cavity (25), the top and bottom sides of the silicon wafer (200) should be etched separately. To do so, an additional process to prevent the opposite side of the wafer from being etched is required. The size of via (26) is properly designed in accordance with the number of the via (26) that are required in the limited device area. Meanwhile, once the formation of cavity (25) and via (26) is completed, remaining etch mask layer pattern (20A and 20B) is preferably removed by wet or dry etching. However, if necessary, the etch mask layer (20A, 20B) can be left to be remained for passivation layer. Further, depending on the desired applications, a new dielectric layer can be formed on one or both sides of the silicon wafer (200).

Subsequently, as shown in FIG. 2f, a photoresist pattern (27) for lift-off, which exposes the cavity interconnection region and bonding pad region, is formed on the back side of the silicon wafer (200), by using a photolithography technique. Because there is a great depth difference between the top surface of the wafer and the bottom surface of the cavity, Spray coating or electro deposition of photoresist is preferred to form photoresist pattern (27).

As a next step, as it is shown in FIG. 2g, cavity interconnection (28A) and wafer bonding pad (28B) are formed by depositing plural layer of metal film by vacuum evaporation or sputtering method and then subsequently by removing the photoresist pattern (27). Meanwhile, in addition to said lift-off method to form cavity interconnection (28A), a selective metal etching method in which metal films present in unwanted area is removed by dry etching or ion milling after depositing multi layer metal films on the whole surface of the wafer by vacuum evaporation or sputtering. Other methods in which single- or multi-layer metal films is deposited by vacuum evaporation or sputtering as a base metal and single- or multi-layer metal substances is additionally coated by plating method can be used. Moreover, cavity interconnection (28A) plays a multiple role of electrically connecting both sides of the silicon wafer (200) and blocking the transport of any gas or liquid substances from the via side to cavity side and as a etch stop layer that prevents a complete penetration of via (26) hole when via (26) is further etched until the bottom contact with lowest layer of cavity interconnection. Cavity interconnection (28A) is formed with plural of metal films having at least two layers, while it is preferred to use a single elemental metal such as Ti or Cr, etc. having an excellent adhesion to silicon or dielectric coating applied onto the silicon or compound substances such as TiN or TiW, etc. for the lowest layer. For the uppermost layer, gold (Au) is preferably used in view of its effectiveness to prevent the oxidation of bottom metals including itself. Moreover, a single elemental metal such as Ni, Pt, Cu or Pd and mixed metal substances such as TiN, TiW, or TaN, etc., can be additionally applied between the adhesive layer and the surface protecting layer as a diffusion barrier.

FIG. 3 shows a layout of a cavity, cavity interconnections and wafer bonding pads which corresponds to FIG. 2g mentioned above. It illustrates the arrangement of cavity interconnection (28A) which is formed inside the cavity (25) and around it. It also shows the arrangement of wafer bonding pad (28B) that has been formed simultaneously with the cavity interconnection (28A).

According to FIG. 3, cavity interconnection (28A) consists of plural of pattern that is non-overlapping to each other, and said cavity interconnection (28A) is connected from the peripheral of the cavity (25) to the bottom of cavity (25) along the sidewall of the cavity (25). Device contact pad region (A) which is present at the perimeter of cavity (25) will eventually be in contact with a device electrode on the device wafer. Via contact pad region (B) which is present at the bottom of cavity (25) is the region in which a contact with via interconnection that is laterly formed on via (26) of the opposite side of the wafer is made. Via contact pad region (B) is placed to face the bottom surface of via (26) which has been formed on the other side of cavity (25). In addition, it is preferred to design the area of via contact pad region (B) is at least larger than the bottom size of via hole (26A) which will contact with cavity interconnection (28A). Furthermore, as it is shown in FIG. 3, wafer bonding pad (28B) is placed to encompass the cavity (25) and all the cavity interconnection (28A) that are arranged around the cavity.

Subsequently, as shown in FIG. 2h, the entire top side surface region of silicon wafer (200) wherein via (26) has been formed is further etched by dry or wet etching to remove remained silicon diaphragm. In this case, etching depth should be the same or greater than the thickness of the remaining silicon substrate. When the etch depth exceeds the thickness of a silicon diaphragm, metals present in the lowest layer of cavity interconnection (28A) that are formed at the bottom side of the cavity at the bottom region of via (26) becomes to be exposed, as it is shown in FIG. 2i. In addition, as the etching is prolonged, the bottom of via (26) starts to be widen. As such, it is preferred to control the via (26A) bottom size by adjusting additional etching time after the etch depth reaches the thickness of the remained silicon diaphragm. In such case, the metal film present at the lowest layer of cavity interconnection (28A) that has been formed at the bottom region of cavity (25) serve as an etch stop layer, therefore preventing a complete penetration of via (26A) through the bottom of cavity (25). The size of via bottom is designed so as to have a minimum area which is required not to significantly increase electrical contact resistance with a cavity interconnection and at the same time to have a maximum area which is required for cavity interconnection to maintain mechanical strength necessary for performing its role as an etch stop layer. Because such process of forming through silicon via (26A) does not involve an etching mask, profile of via (26) is preserved as it is regardless of isotropic or anisotropic nature of an etching process.

Next, as shown in FIG. 2j, with a photolithography process and a deposition process, plural layer of metal films are deposited on the top side of silicon wafer (200) wherein through silicon via (26A) has been formed, in order to form via interconnection (29) at certain regions of the wafer surface, including the inside of through silicon via (26A) Preferred constitution of the multi-layer metal films that forms via interconnection (29) is Cr or Ti, etc. having good adhesion to substrate as a lowest layer and Au having a wire bonding capability and providing a passivation against contamination from outside as a uppermost layer. Between said lowest layer and the uppermost layer, Ni, Pt, Cu or TiW, etc., which have a good diffusion barrier property can be additionally inserted as a single-layer or a multi-layer. Meanwhile, in addition to the multi-layer metal films, Au, Ni, or Cu can be further deposited on the via interconnection by electro plating or electroless plating.

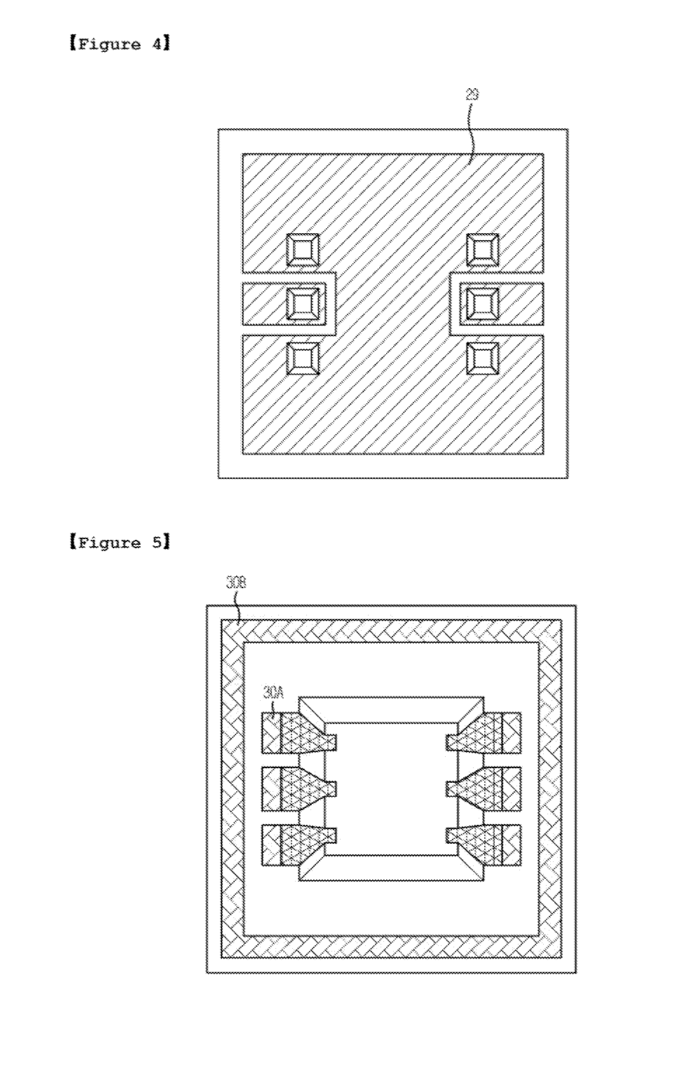

FIG. 4 shows a layout of vias and via interconnections which corresponds to FIG. 2j mentioned above.

According to FIG. 4, via interconnection (29) is in contact with cavity interconnection (28A) through the bottom of through silicon via (26A), and it has contact pads at pre defined area of the surface of silicon wafer (200). via (26A) interconnections which is connected to a ground pad of device in device wafer can be combined as ground pad.

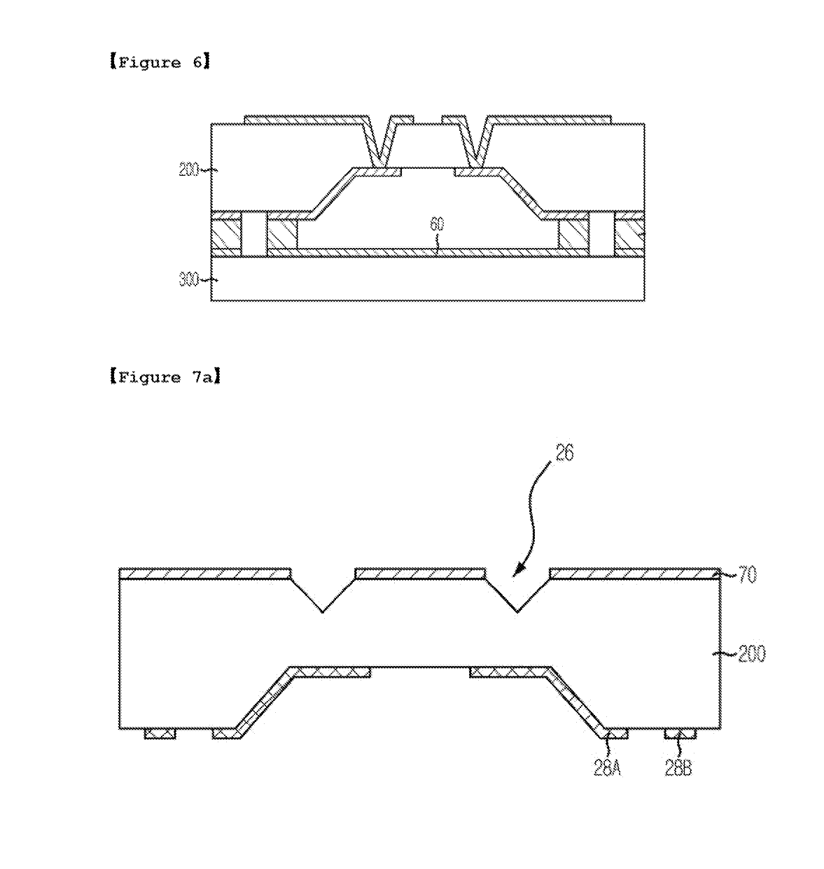

Next, as shown in FIG. 2k, device contact pad (30A), which is required for an electrical contact with device wafer, is formed on device contact pad region (A) of cavity interconnection (28A), and hermetic seal ring (30B), which is required for mechanical joining and hermetic sealing of cavity, is also formed on wafer bonding pad (28B). Device contact pad (30A) and hermetic seal ring (30B) can be formed with the same method as described for the formation of cavity interconnection (28A) described above. Device contact pad (30A) and hermetic seal ring (30B) should provide not only the mechanical bonding and the electrical interconnection between cap wafer (200) and device wafer but also a hermetic sealing of the cavity. For such reason, materials having good electric conductivity that is selected from the group of Cu, Au, Sn, In, Au—Sn alloy, Sn—Ag alloy or Au/Sn multi layer film in which Au and Sn are alternatingly stacked with more than one layer is preferred. Depending on specific conditions, in order to prevent mixing of a bonding material that has been used for device contact pad (30A) and hermetic seal ring (30B) with the uppermost metal film of cavity interconnection (28A single- or multi-layer metal films comprising of Ni, Pt, Cr/Ni, Ti/Ni, Cr/Pt, or TiW, etc. can be additionally applied. FIG. 5 shows a layout of wafer bonding pads and wafer seal ring which corresponds to FIG. 2k mentioned above, from which the arrangement of device contact pad (30A) and hermetic seal ring (30B) can be easily identified.

Cap wafer (200) which has been prepared with the method described above is bonded with device wafer (300) by any method including thermal reflow, thermo-compression and ultrasonic bonding, etc. to complete the primary packaging process (see, FIG. 6). Number ‘60’ in FIG. 6 indicates an electrode that is formed on the device wafer (300).

Finally, bonded wafer is separated into individual chips by sawing and then the individual chips are mounted on a PCB after appropriate measurements and test procedures. Meanwhile, said method for preparing a cap wafer relates to the mounting of chips on PCB by using a conventional die bonding technique. Alternatively, when a flip chip bonding technique is used for the mounting of chips on PCB, it is possible to additionally form a solder bump over via interconnection (29) pattern of the cap wafer. Solder bumps can be formed using the same method described for the preparation of the bonding pad mentioned above or it can be formed by other various methods including solder jet method and stud bumping method, etc.

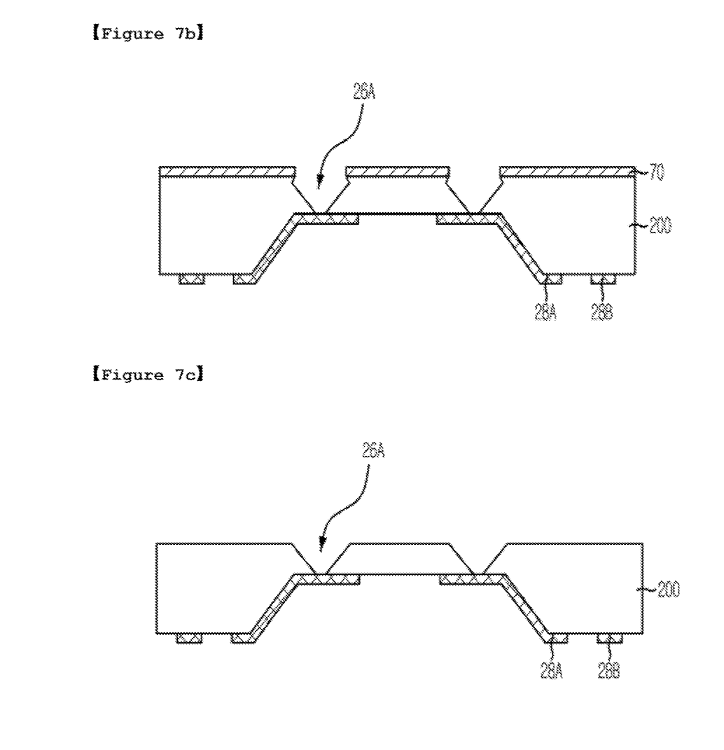

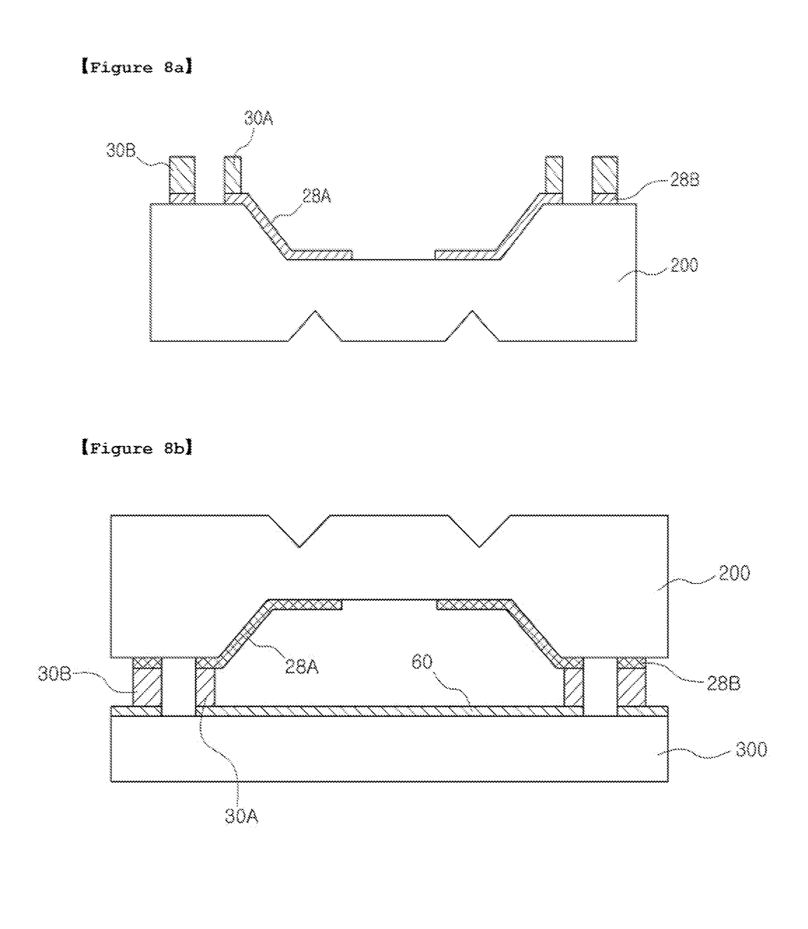

FIGS. 7a to 7c are related to another example to open via (26A) contact of which preparation has been illustrated in FIGS. 2h and 2i mentioned above.

Referring to FIG. 7a, over the entire surface of silicon wafer, photoresist (70) is coated except via (26) region formed on the top surface of the silicon wafer (200).

Next, as shown in FIG. 7b, the temporary silicon diaphragm under the via (26) bottom is removed by additionally etching the via (26) with isotropic dry etching. In the case of isotropic etching, etching occurs almost equally over all the surface of via (26A). Lower part of via (26A) roughly maintains its original inverse pyramidal shape, but upper part of via has a negative side wall (e.g., under cut) due to the characteristics of anisotropic etching. When the via (26A) bottom reached to via contact pad region (B) of cavity interconnection (23A), further etching is stopped by the lowest metal film of cavity interconnection (28A). As a result, further etching is only progressed along the side wall of via (26A) so that the opened bottom area of via (26A) would become wider and wider. Therefore, by controlling etching time, it is possible to suitably adjust the bottom size of through silicon via (26A). The above-described method for removing temporary silicon diaphragm result in an under cut (or vertical side wall in case of anisotropic etching) at the surface region of via (26A) as mentioned above. Such under cut provides a significant problem for post processing steps such as photoresist coating and metal film deposition inside of through silicon via (26A). For such reason, it is necessary to remove some portion of silicon substrate wherein under cut is present by mechanical polishing or dry etching, as it is depicted in FIG. 7c.

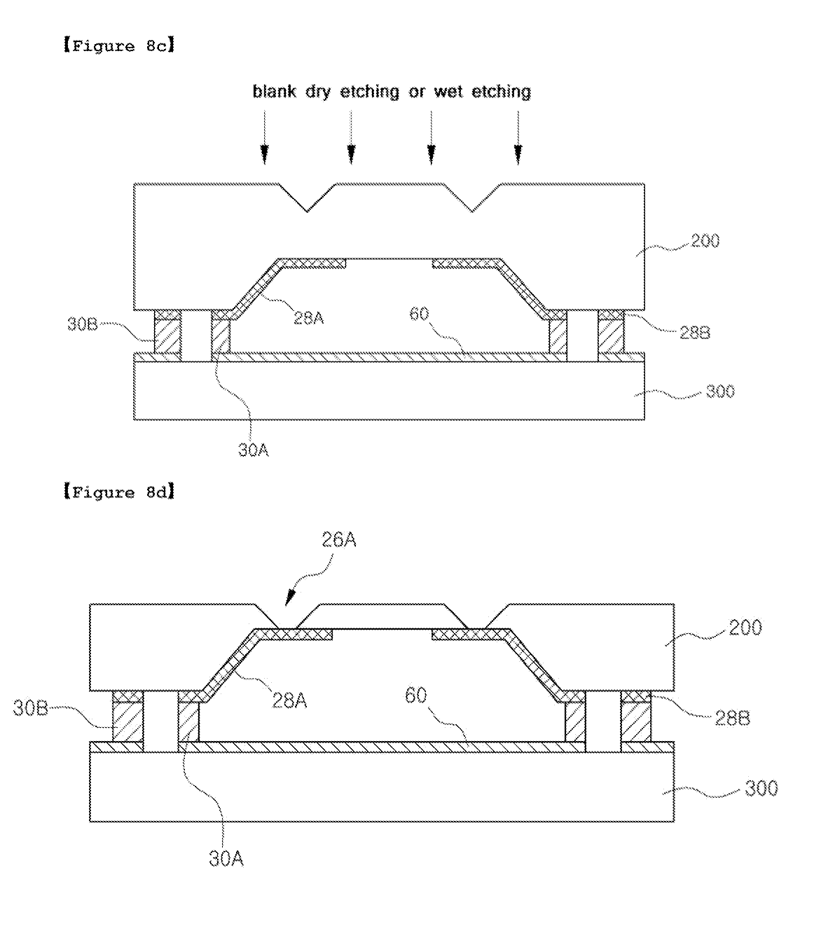

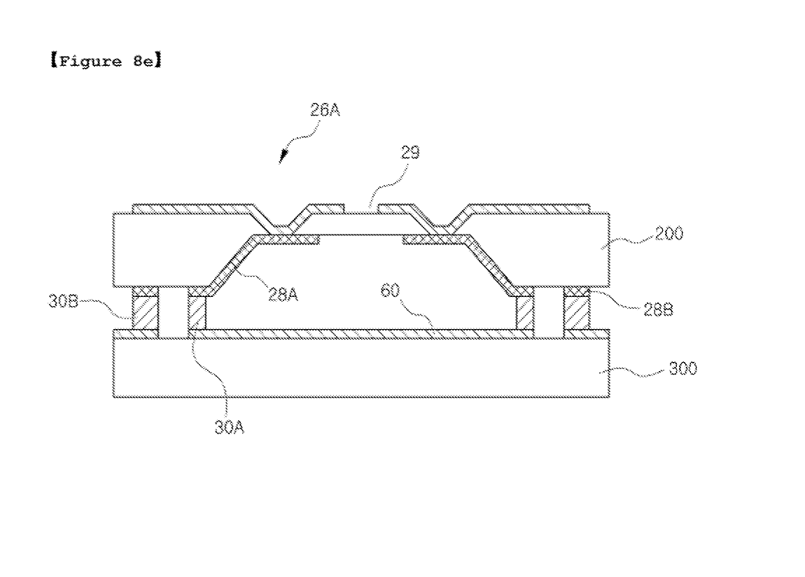

Meanwhile, as another example for a wafer bonded packaging method of the present invention, after completing the process steps of FIGS. 2a to 2g described above, the process is continued by bonding a cap wafer with a device wafer as it is illustrated in FIGS. 8a to 8e.

Referring to FIG. 8a, after completing the steps shown in FIGS. 2a to 2g, cavity interconnection (28A) and wafer bonding pad (28B) are formed on the back side of the silicon wafer. Subsequently, device contact pad (30A), which is required for an electrical contact with the device wafer, is formed on device contact pad region (A) of cavity interconnection (25A), and hermetic seal ring (30B), which is required for mechanical conjunction and hermetic sealing of device wafer, is also formed on wafer bonding pad (28B).

As it is shown in FIG. 5b, the silicon cap wafer prepared according to the process illustrated in FIG. 8a is bonded with device wafer (300).

As it is shown in FIG. 5c, the entire top side surface region of silicon wafer (200) wherein via (26) has been formed is further etched by dry or wet etching without etch mask to remove remained silicon substrate.

FIG. 5d relates to a step of forming through silicon via (26A). As it is described for FIG. 2i, the lowest metal layer of cavity interconnection (28A) serves as an etch stop layer so that a complete penetration of via through the bottom of cavity (25) is prevented.

FIG. 8e relates to a step of forming via interconnection (29) as it is explained in FIG. 2j. Specifically, via interconnection (29) is in contact with cavity interconnection (28A) through the bottom of the through silicon via (26A), and it has contact pads at pre defined area of the surface of silicon wafer (200).

Furthermore, for a process in which wafer bonding with a device wafer is carried out first as shown in FIGS. 8a to 8e, a method described in FIGS. 7a to 7c can be used for the formation of through silicon via.

The technical spirit of the present invention is specifically described in view of the above-described preferred Examples. However, it should be understood that they are only to assist understanding the present invention but are not to be construed in any way imposing limitation upon the scope thereof. In addition, those skilled in the art will easily recognize that various further examples and embodiments are possible within the scope of the present invention.

For example, for the above-described Examples, the step of forming cavity etch window (22) and the step of forming via etch window (24) can be carried out in any order.

### INDUSTRIAL APPLICABILITY

The present invention described above is advantageous in that for preparing a cap wafer by excluding; a trench formation process by deep reactive ion etching of silicon substrate and Cu filling process; SOI substrate is not used and a process for forming through silicon via interconnection is simplified so that the overall production cost can be significantly reduced.

1. A method for preparing a cap wafer for wafer bonded packaging comprising the steps of:
i) forming an etch mask layer on Stop and back sides of a silicon wafer;
ii) selectively removing said etch mask layer to form a cavity etch window on the back side of said silicon wafer, and then forming a via etch window on the top side of said silicon wafer to overlap with said cavity etch window;
iii) forming a cavity and a via by wet etching of said silicon wafer that has been exposed by said cavity etch window and said via etch window, provided that a silicon diaphragm with a certain thickness is temporarily maintained between said cavity and said via;
iv) forming a cavity interconnection and a wafer bonding pad on the back side of said silicon wafer to which said cavity has been formed;
v) forming a through silicon via by removing the temporary silicon diaphragm under the bottom of said via so that the bottom of said via is in contact with the cavity interconnection;
vi) forming a via interconnection which contacts said cavity interconnection on the top side of said silicon wafer with said through silicon via formed thereon; and
vii) with a metallic bonding material, forming a device contact pad and a hermetic seal ring, respectively, on said cavity interconnection which is present on periphery of said cavity and on top of said wafer bonding pad.

2. The method for preparing a cap wafer for wafer bonding of claim 1, wherein the through silicon via is formed by dry or wet etching the entire top surface of said silicon wafer without etch mask.

3. The method for preparing a cap wafer for wafer bonding of claim 1, wherein the step of forming said through silicon via comprises the steps of:
i) forming a photoresist pattern over the top surface of said silicon wafer except the via region;
ii) further etching the remained silicon substrate under said via by dry etching method; and
iii) by mechanical polishing, removing the top surface of said silicon wafer to a certain depth where a negative profile of said via is present by under cut.

4. The method for preparing a cap wafer for wafer bonding of claim 1, wherein after the step of forming said cavity and via, the step of removing said etch mask layer remained on the top and back sides of said silicon wafer is more comprised.

5. The method for preparing a cap wafer for wafer bonding of claim 1, wherein said silicon wafer has a 100 crystal plane, and said cavity etch window and said via etch window are aligned to be parallel with the 110 crystalline orientation.

6. The method for preparing a cap wafer for wafer bonding of claim 1, wherein said etch mask layer is composed of one selected from silicon oxide layer, silicon nitride layer and stacked layer of silicon oxide layer/silicon nitride layer.

7. The method for preparing a cap wafer for wafer bonding of claim 4, wherein after the step of removing said etch mask layer remained on the top and back sides of said silicon wafer, the step of forming a dielectric layer on one or both surface of said silicon wafer is more comprised.

8. The method for preparing a cap wafer for wafer bonding of claim 1, wherein said cavity interconnection, said wafer bonding pad and said via interconnection are respectively formed by a lift-off method.

9. The method for preparing a cap wafer for wafer bonding of claim 1, wherein said cavity interconnection, said wafer bonding pad and said via interconnection are respectively formed by a selective metal etching method.

10. The method for preparing a cap wafer for wafer bonding of claim 1, wherein said cavity interconnection, said wafer bonding pad and said via interconnection are respectively formed by plating additional metal film said cavity interconnection, said wafer bonding pad and said via interconnection.

11. The method for preparing a cap wafer for wafer bonding of claim 1, wherein said cavity interconnection and said wafer bonding pad comprise the layers of:
i) a lowest layer which is at least one selected from Ti, Cr, TiN and TiW;
ii) a diffusion barrier layer which is at least one selected from Ni, Pt, Cu, Pd, TiN, TiW and TaN; and
iii) an uppermost layer of Au.

12. The method for preparing a cap wafer for wafer bonding of claim 1, wherein said metallic bonding material is composed of at least one selected from Au, Sn, In, Au—Sn alloy, Sn—Ag alloy, Au/Sn multi layer.

13. The method for preparing a cap wafer for wafer bonding of claim 12, wherein at the bottom of said metallic bonding material a diffusion barrier metal layer selected from Ni, Pt, Cr/Ni, Ti/Ni and Cr/Pt is more comprised.

14. Wafer bonded packaging method comprising the steps of:
i) forming an etch mask layer on top and back sides of a silicon wafer;
ii) patterning said etch mask layer to form a cavity etch window on the back side of silicon wafer, and then forming a via etch window on the top side of said silicon wafer to overlap with said cavity etch window;
iii) forming a cavity and a via by wet etching of said silicon wafer that has been exposed by said cavity etch window and said via etch window, provided that a silicon diaphragm with certain thickness is temporarily maintained between said cavity and said via;
iv) forming a cavity interconnection and a wafer bonding pad on the back side of said silicon wafer to which said cavity has been formed;
v) forming a through silicon via by removing the temporary silicon diaphragm under the bottom of said via in contact with the cavity interconnection;
vi) forming a via interconnection which contacts said cavity interconnection on the top side of said silicon wafer with said through silicon via formed thereon;
vii) with a metallic bonding material, forming a device contact pad and a hermetic seal ring, respectively on said cavity interconnection which is present on the periphery of said cavity and on top of said wafer bonding pad; and
viii) bonding the silicon cap wafer wherein said device contact pad and said hermetic seal ring have been formed to the device wafer wherein the device has been formed.

15. A water bonded packaging method comprising the steps of:
i) forming an etch mask layer on top and back sides of a silicon wafer;
ii) selectively removing the said etch mask layer to form a cavity etch window on the back side of said silicon wafer, and then forming a via etch window on the top side of said silicon wafer to overlap with said cavity etch window;
iii) forming a cavity and a via by wet etching of said silicon wafer that has been exposed by said cavity etch window and said via etch window, provided that a silicon diaphragm with certain thickness is maintained between said cavity and said via;
iv) forming a cavity interconnection and a wafer bonding pad on the back side of said silicon wafer to which said cavity has been formed;
v) with a metallic bonding material, forming a device contact pad and a hermetic seal ring, respectively on said cavity interconnection which is present on the periphery of said cavity and on top of said wafer bonding pad;
vi) bonding the silicon cap wafer wherein said device contact pad and said hermetic seal ring have been formed to the device wafer wherein the device has been formed;
vii) forming a through silicon via by removing the temporary silicon diaphragm under the bottom of said via that the bottom of said via is in contact with the cavity interconnection; and
viii) forming a via interconnection which contacts said cavity interconnection on the top side of said silicon wafer with said through silicon via formed thereon.

16. The method for preparing a cap wafer for wafer bonding of claim 14, wherein step of forming said through silicon via is provided by dry or wet etching of the entire top surface of said silicon wafer without an etch mask.

17. The method for preparing a cap wafer for wafer bonding of claim 14, wherein the step of forming said through via comprises the steps of:
i) forming a photoresist pattern over the top surface of said silicon wafer except the via region;
ii) further etching the remained silicon substrate under said via by a dry etching method; and
iii) by mechanical polishing, removing the top surface of said silicon wafer to a certain depth where a negative profile of said via is present by under cut.

18. The method for preparing a cap wafer for wafer bonding of claim 14, wherein said metallic bonding material is composed of at least one selected from Au, Sn, In, Au—Sn alloy, Sn—Ag alloy, Au/Sn multi layer.

19. The method for preparing a cap wafer for wafer bonding of claim 15, wherein step of forming said through silicon via is provided by dry or wet etching of the entire top surface of said silicon wafer without an etch mask.

20. The method for preparing a cap wafer for wafer bonding of claim 15, wherein the step of forming said through via comprises the steps of:
i) forming a photoresist pattern over the top surface of said silicon wafer except the via region;
ii) further etching the remained silicon substrate under neath of said via by a dry etching method; and
iii) by mechanical polishing, removing the top surface of said silicon wafer to a certain depth where a negative profile of said via is present by under cut.

21. The method for preparing a cap wafer for wafer bonding of claim 15, wherein said metallic bonding material is composed of at least one selected from Au, Sn, In, Au—Sn alloy, Sn—Ag alloy, Au/Sn multi layer.
